(19) United States
(12) Patent Application Publication
(10) Pub. No.: US 2025/0365931 A1
(43) Pub. Date: Nov. 27, 2025

(54) THREE-DIMENSIONAL SEMICONDUCTOR DEVICES AND METHODS FOR FORMING THE SAME

(71) Applicant: Yangtze Memory Technologies Co., Ltd., Wuhan (CN)

(72) Inventors: Yonggang YANG, Wuhan (CN); Yuhuan ZHENG, Wuhan (CN)

(21) Appl. No.: 18/791,418

(22) Filed: Jul. 31, 2024

Related U.S. Application Data
(63) Continuation of application No. PCT/CN2024/095125, filed on May 24, 2024.

(51) Int. Cl. H10B 12/00

(52) U.S. Cl. CPC H10B 12/315; H10B 12/033

(57) ABSTRACT

The present disclosure relates to methods, devices, systems, and techniques for managing three-dimensional (3D) semiconductor devices. An example semiconductor device includes an array of memory cells. A memory cell in the array of memory cells includes a first vertical transistor and a first capacitor stacked along a first direction. The first capacitor includes a first electrode including a filler structure and a conductive layer surrounding the filler structure. The first electrode of the first capacitor is in contact with a first supporting structure and a second supporting structure. The first electrode of the first capacitor and the first supporting structure are disposed along a second direction. The first electrode of the first capacitor and the second supporting structure are disposed along the second direction. The first supporting structure and the second supporting structure extend along the second direction by different lengths. The second direction is perpendicular to the first direction.

### CROSS-REFERENCE TO RELATED APPLICATIONS

This application is a continuation of International Application No. PCT/CN2024/095125, filed on May 24, 2024, the disclosure of which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures.

### SUMMARY

The present disclosure describes methods, devices, systems, and techniques for managing three-dimensional (3D) semiconductor devices.

One aspect of the present disclosure features a semiconductor device. The semiconductor device includes an array of memory cells. A memory cell in the array of memory cells includes a first vertical transistor and a first capacitor stacked along a first direction. The first capacitor includes a first electrode including a filler structure and a conductive layer surrounding the filler structure. The first electrode of the first capacitor is in contact with a first supporting structure and a second supporting structure. The first electrode of the first capacitor and the first supporting structure are disposed along a second direction. The first electrode of the first capacitor and the second supporting structure are disposed along the second direction. The first supporting structure and the second supporting structure extend along the second direction by different lengths. The second direction is perpendicular to the first direction. The first supporting structure and the second supporting structure are between a first end of the first electrode of the first capacitor and a second end of the first electrode of the first capacitor along the first direction. The first supporting structure is closer to the first end of the first electrode of the first capacitor than the second supporting structure along the first direction. The second supporting structure is closer to the second end of the first electrode of the first capacitor than the first supporting structure along the first direction.

In some implementations, the second end of the first electrode of the first capacitor is in contact with a third supporting structure. The second end of the first electrode of the first capacitor and the third supporting structure are disposed along the second direction.

In some implementations, the first capacitor further includes a dielectric layer and a second electrode, the dielectric layer is in contact with the conductive layer of the first electrode of the first capacitor, and the second electrode of the first capacitor is in contact with the dielectric layer of the first capacitor.

In some implementations, the first supporting structure has a first end and a second end positioned along the second direction, the first end is in contact with the conductive layer of the first electrode of the first capacitor, the first end and the conductive layer of the first electrode of the first capacitor are disposed along the second direction, the second end is in contact with the dielectric layer of the first capacitor, and the second end and the dielectric layer of the first capacitor are disposed along the second direction.

In some implementations, the array of memory cells includes a second capacitor adjacent to the first capacitor, the first supporting structure has a first end and a second end positioned along the second direction, the first end is in contact with the conductive layer of the first electrode of the first capacitor, the first end and the conductive layer of the first electrode of the first capacitor are disposed along the second direction, the second end is in contact with a first electrode of the second capacitor, and the second end and the first electrode of the second capacitor are disposed along the second direction.

In some implementations, the semiconductor device includes a first semiconductor structure and a second semiconductor structure connected to the first semiconductor structure, the first semiconductor structure includes the array of memory cells, and the second semiconductor structure includes a control circuit configured to control the array of memory cells.

In some implementations, the first semiconductor structure is bonded to the second semiconductor structure through a bonding structure, the first capacitor is coupled to the control circuit through the bonding structure, the first vertical transistor, the first capacitor, and the bonding structure are disposed along the first direction, and the first vertical transistor is positioned between the first capacitor and the bonding structure.

In some implementations, the filler structure of the first electrode of the first capacitor includes polysilicon, and the conductive layer of the first electrode of the first capacitor includes titanium nitride (TiN).

In some implementations, the first vertical transistor includes a transistor body and a gate structure, the transistor body extends along the first direction and includes a first terminal and a second terminal opposite to the first terminal, the gate structure is adjacent to the transistor body, the gate structure and the transistor body are disposed along the second direction, the first terminal is in contact with the first electrode of the first capacitor, and the first terminal and the first electrode of the first capacitor are disposed along the first direction.

In some implementations, the transistor body includes at least one of polysilicon, indium gallium zinc oxide (IGZO), or indium gallium silicon oxide (IGSO).

In some implementations, the gate structure includes one of a single-side gate structure, a dual-side gate structure, a triple-side gate structure, or a gate-all-around (GAA) structure.

Another aspect of the present disclosure features a method including providing a first semiconductor structure of the semiconductor device. The method further includes forming an array of memory cells in the first semiconductor structure. A memory cell in the array of memory cells includes a first vertical transistor and a first capacitor stacked along a first direction. A first electrode of the first capacitor is in contact with a first supporting structure and a second supporting structure. The first electrode of the first capacitor and the first supporting structure are disposed along a second direction. The first electrode of the first capacitor and the second supporting structure are disposed along the second direction. The first supporting structure and the second supporting structure extend along the second direction by different lengths. The second direction is perpendicular to the first direction. The first supporting structure and the second supporting structure are between a first end of the first electrode of the first capacitor and a second end of the first electrode of the first capacitor along the first direction. The first supporting structure is closer to the first end of the first electrode of the first capacitor than the second supporting structure along the first direction. The second supporting structure is closer to the second end of the first electrode of the first capacitor than the first supporting structure along the first direction.

In some implementations, forming the array of memory cells includes forming an array of capacitors including the first capacitor and forming an array of vertical transistors including the first vertical transistor. Forming the array of capacitors includes forming a first supporting layer, a first sacrificial layer, a second supporting layer, a second sacrificial layer, and a third supporting layer stacked on top of a substrate of the first semiconductor structure along the first direction. The first sacrificial layer is between the first supporting layer and the second supporting layer along the first direction. The second sacrificial layer is between the second supporting layer and the third supporting layer along the first direction. The first supporting layer includes first sacrificial pads and a first dielectric material isolating the first sacrificial pads along the second direction. The second supporting layer includes second sacrificial pads and a second dielectric material isolating the second sacrificial pads along the second direction. The first sacrificial pads and the second sacrificial pads have different layouts. The third supporting layer includes a third dielectric material.

In some implementations, forming the array of capacitors further includes: forming an array of capacitor holes extending through the third supporting layer, the second sacrificial layer, the second supporting layer, the first sacrificial layer, and the first supporting layer and into the substrate along the first direction; and forming a first array of electrodes by depositing a conductive material on inner surfaces of the array of capacitor holes and filling a filler material into the array of capacitor holes, where the first array of electrodes includes the first electrode.

In some implementations, forming the array of vertical transistors includes forming the array of vertical transistors on top of the third supporting layer. The first vertical transistor includes a transistor body and a gate structure. The transistor body has a first terminal and a second terminal on opposite ends of the transistor body along the first direction. The gate structure is adjacent to the transistor body along the second direction. The first terminal is in contact with the first electrode. The first terminal and the first electrode are disposed along the first direction. The transistor body includes at least one of polysilicon, IGZO, or IGSO. The gate structure includes one of a single-side gate structure, a dual-side gate structure, a triple-side gate structure, or a GAA structure.

In some implementations, the method further includes: flipping the first semiconductor structure upside down; bonding the first semiconductor structure to a second semiconductor structure including a control circuit; and removing the substrate.

In some implementations, forming the array of capacitors further includes removing the first sacrificial pads in the first supporting layer, the first sacrificial layer, the second sacrificial pads in the second supporting layer, and the second sacrificial layer by a same etching process. A remaining part of the first supporting layer includes the first supporting structure, and a remaining part of the second supporting layer includes the second supporting structure.

In some implementations, forming the array of capacitors further includes: forming an array of capacitor bodies by depositing a dielectric layer surrounding the first array of electrodes and the remaining part of the first supporting layer and the remaining part of the second supporting layer, where the array of capacitor bodies includes a capacitor body of the first capacitor formed by a portion of the dielectric layer that is in contact with the first electrode, the first supporting structure, and the second supporting structure; and forming a second array of electrodes by depositing at least one conductive layer surrounding the dielectric layer, where the second array of electrodes includes a second electrode of the first capacitor formed by a portion of the at least one conductive layer that is in contact with the capacitor body of the first capacitor.

A further aspect of the present disclosure features a memory system. The memory system includes a memory device and a memory controller coupled to the memory device and configured to control the memory device. The memory device includes an array of memory cells. A memory cell in the array of memory cells includes a first vertical transistor and a first capacitor stacked along a first direction. The first capacitor includes a first electrode including a filler structure and a conductive layer surrounding the filler structure. The first electrode of the first capacitor is in contact with a first supporting structure and a second supporting structure. The first electrode of the first capacitor and the first supporting structure are disposed along a second direction. The first electrode of the first capacitor and the second supporting structure are disposed along the second direction. The first supporting structure and the second supporting structure extend along the second direction by different lengths. The second direction is perpendicular to the first direction. The first supporting structure and the second supporting structure are between a first end of the first electrode of the first capacitor and a second end of the first electrode of the first capacitor along the first direction. The first supporting structure is closer to the first end of the first electrode of the first capacitor than the second supporting structure along the first direction. The second supporting structure is closer to the second end of the first electrode of the first capacitor than the first supporting structure along the first direction.

In some implementations, the first capacitor further includes a dielectric layer and a second electrode, the dielectric layer is in contact with the conductive layer of the first electrode of the first capacitor, and the second electrode of the first capacitor is in contact with the dielectric layer of the first capacitor.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIGS. 1A-1B illustrate an example semiconductor device.

FIGS. 2A-2F illustrate an example process of manufacturing a semiconductor device.

FIGS. 3A-3C illustrate example layouts of supporting layer formed in the process of FIGS. 2A-2E.

FIG. 4 illustrates a flow chart of an example process of manufacturing a semiconductor device.

FIG. 5 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Manufacturing of Dynamic Random Access Memory (DRAM) devices may have thermal budget issues. In some DRAM techniques, vertical transistor formation often involves implantation under high temperatures. However, high-k materials in capacitors of a DRAM device may not perform well when the temperature is high. Because of this constraint, implantations for transistor terminals can be carried out prior to deposition of the high-k materials, which may lead to complex manufacturing process, particularly for drain implantations. Because drains can be at the bottom of transistor bodies, it can be challenging for dopants to reach them effectively from the top of transistor bodies. In addition, it is desirable to increase the capacitance of the capacitors of the DRAM device. To this end, the height (e.g., a size along the vertical direction) of the capacitors can be increased while the pitch of the capacitors in a horizontal direction is maintained. However, the capacitors with high aspect ratios may tilt or even collapse during the manufacturing process, thereby affecting the reliability and performance of the DRAM devices and reducing the production yield.

In one or more implementations of the present disclosure, an example semiconductor device is provided. Vertical transistors of the semiconductor device can be formed before the deposition of high-k materials of capacitors of the semiconductor device. Manufacturing of the semiconductor device includes forming capacitor holes that extend into a substrate of the semiconductor device and supporting layers that include sacrificial pads with different layouts.

Implementations of the present disclosure can provide one or more of the following technical advantages and/or benefits. For example, thermal budget can be improved because processes requiring high temperature, e.g., implantation during vertical transistors processing, are conducted before the deposition of high-k materials for capacitors. In addition, the sacrificial pads in the supporting layers can be etched off during an etching process, which allows an etchant to flow into sacrificial layers between the supporting layers, hence removing the sacrificial layers in the same etching process. The supporting layers described in the present disclosure can form supporting structures at both sides of a capacitor (e.g., with reference to the vertical direction), thereby preventing the capacitor from tilting or collapsing. Furthermore, the substrate of the semiconductor device can also provide support to the capacitors of the semiconductor devices during fabrication. The deepened capacitor holes can enlarge space for the capacitors in the vertical direction while maintaining the pitch of the capacitors in the horizontal direction, thereby increasing the capacitance of the capacitors.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

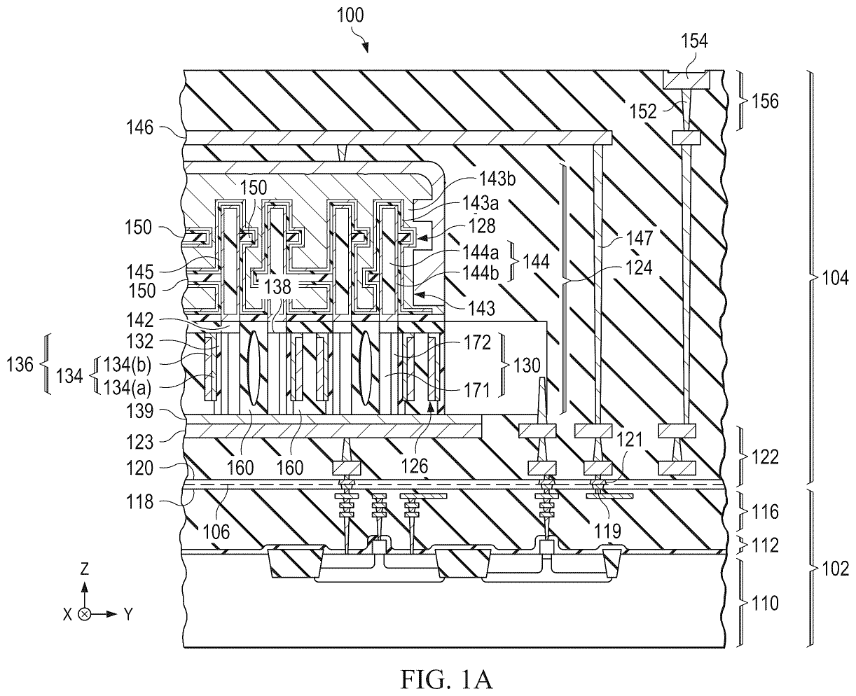

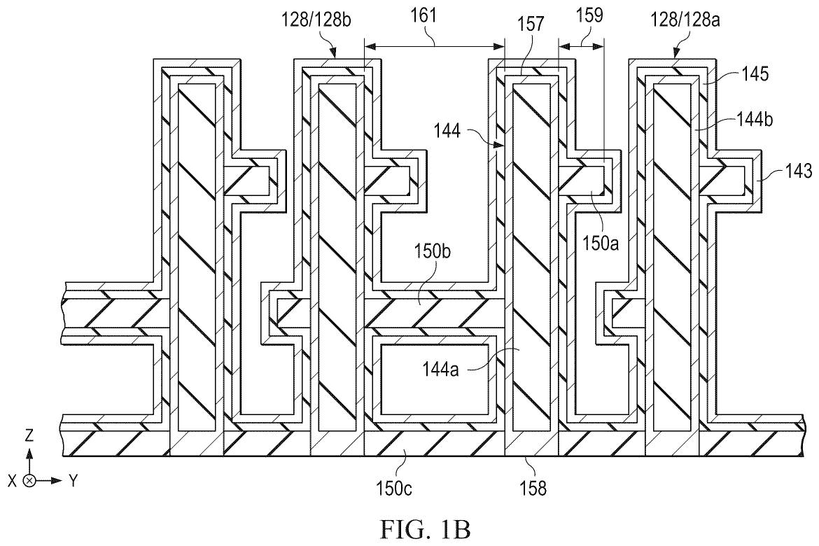

It is noted that X, Y, and Z axes (also referred to as X, Y, and Z directions) are included in FIGS. 1A-1B to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a side view of a cross-section of an example 3D semiconductor device 100. The 3D semiconductor device 100 can be a 3D dynamic random-access memory (DRAM). It is understood that FIG. 1A is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1A, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on the substrate 110. In some implementations, the peripheral circuits 112 include a plurality of transistors (e.g., planar transistors and/or 3D transistors). Trench isolations (e.g., shallow trench isolations (STIs)) and doped regions (e.g., wells, sources, and drains of transistors) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1A, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1A, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1A. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit lines 123 are made of conductive materials, e.g., W, Co, Cu, Al, or any combination thereof. In some implementations, the bit lines 123 are made of composite conductive material, including without limitations WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die.

In some implementations, a semiconductor device can include multiple array dies (e.g., the second semiconductor structure 104) and a CMOS die (e.g., the first semiconductor structure 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a transistor body 130 (the active region in which a channel can form) extending vertically (e.g., in the Z direction), and a gate structure 136 in contact with one side of transistor body 130. In a single-gate vertical transistor, the transistor body 130 can have a cuboid shape or a cylinder shape, and the gate structure 136 can abut a single side of transistor body 130 in a plane view, e.g., as shown in FIG. 1A. In some implementations, the gate structure 136 includes a gate electrode 134 and a gate dielectric 132 laterally between the gate electrode 134 and the transistor body 130 in a bit line direction (e.g., in the Y direction). In some implementations, the gate dielectric 132 abuts one side of the transistor body 130, and the gate electrode 134 abuts the gate dielectric 132.

In some implementations, the gate electrode 134 includes multiple conductive layers, such as a W layer over a TiN layer. As illustrated in FIG. 1A, the gate electrode 134 includes two layers, first gate electrode layer 134(a) (e.g., TiN) and second gate electrode layer 134(b) (e.g., W). The first gate electrode layer 134(a) can have an angled or curved end, e.g., a L-shape in X-Z plane view. The L-shaped gate electrode 134(a) includes two portions: a first portion extending along the Z direction or along an inclined angle relative to the Z direction and a second portion extending along the Y direction. In addition, the second portion of gate electrode 134(a) can be closer to first terminals 138 than second terminals 139.

It is understood that the structure of configuration of a gate structure 136 is not limited to the example in FIG. 1A and may include any suitable structure and configuration, such as a single-side gate structure, a dual-side gate structure, a triple-side gate structure, or a gate-all-around (GAA) structure.

As shown in FIG. 1A, in some implementations, the transistor body 130 has two ends (the upper end and lower end in FIG. 1A) in the vertical direction (e.g., the Z direction), and at least one end (e.g., the lower end) extends beyond gate dielectric 132 in the vertical direction (e.g., the Z direction) into the ILD layers (not shown). In some implementations, one end (e.g., the upper end) of the transistor body 130 is flush with the respective end (e.g., the upper end) of the gate dielectric 132. In some implementations, both ends (the upper end and lower end) of the transistor body 130 extend beyond the gate electrode 134, respectively, in the vertical direction (e.g., the Z direction) into ILD layers (not shown). That is, the transistor body 130 can have a larger vertical dimension (e.g., the depth) than that of the gate electrode 134 (e.g., in the Z direction), and neither the upper end nor the lower end of transistor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a first terminal 138 and a second terminal 139 (e.g., a source and a drain) disposed at the two ends (the upper end and lower end) of the transistor body 130, respectively, in the vertical direction (e.g., the Z direction). In some implementations, the first terminal 138 (e.g., at the upper end in FIG. 1A) is coupled to the capacitor 128, and the second terminal 139 (e.g., at the lower end in FIG. 1A) is coupled to the bit line 123. That is, the vertical transistor 126 can have a first terminal in the positive Z direction and a second terminal opposite to the first terminal in the negative Z direction, as shown in FIG. 1A.

In some implementations, the transistor body 130 includes semiconductor materials, such as single crystalline silicon, polysilicon, amorphous silicon, Ge, indium gallium zinc oxide (IGZO), or indium gallium silicon oxide (IGSO), any other semiconductor materials, or any combinations thereof. Terminals 138 and 139 can be doped with N+ type dopants (e.g., Phosphorus (P) or Arsenic (As)) or P-type dopants (e.g., Boron (B) or Gallium (Ga)) at a desired doping level, or include Silicon Germanium (SiGe).

In some implementations, the transistor body 130 includes a first body 171 and a second body 172 that are laterally in contact with each other. In some implementations, the second body 172 has a higher electron mobility than the first body 171, and the second body 172 is disposed laterally between the first body 171 and the gate dielectric 132 along the BL direction (e.g., the Y direction).

In some implementations, a silicide layer, such as a metal silicide layer, is formed between the second terminal 139 of the vertical transistor 126 and the bit line 123 as the bit line contact or between the first terminal 138 of the vertical transistor 126 and the first electrode of the capacitor 128 as capacitor contact 142 to reduce the contact resistance. In some implementations, gate dielectric 132 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal. High-k materials can include any material with a dielectric constant higher than or equal to a threshold value (e.g., 3.9).

As described above, since the gate electrode 134 may be part of a word line or extend in the word line direction (e.g., the X direction) as a word line, the second semiconductor structure 104 of the 3D semiconductor device 100 can also include a plurality of word lines each extending in the word line direction. Each word line 134 can be coupled to a row of DRAM cells 124. That is, the bit line 123 and the word line 134 can extend in two perpendicular lateral directions, and the transistor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1A.

In some implementations, as shown in FIG. 1A, the vertical transistor 126 extends vertically through and contacts the word lines 134, and the second terminal 139 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the Y direction). As shown in FIG. 1A, two adjacent vertical transistors 126 in the bit line direction are mirror-symmetric to one another with respect to a trench isolating region 160. That is, the second semiconductor structure 104 can include a plurality of trench isolations 160 each extending in the word line direction (the X direction) in parallel with word lines 134 and disposed between transistor bodies 130 of two adjacent rows of the vertical transistors 126. In some implementations, the rows of vertical transistors 126 separated by the trench isolating region 160 are mirror-symmetric to one another with respect to the trench isolating region 160. The trench isolating region 160 can be formed with dielectric materials including, but not limited to, silicon oxide, silicon nitride, silicon oxynitride, low-k dielectrics, or any combination thereof. It is understood that the trench isolating region 160 may include an air gap each disposed laterally between adjacent transistor bodies 130. Air gaps may be formed due to the relatively small pitches of vertical transistors 126 in the bit line direction (e.g., the Y direction). On the other hand, the relatively large dielectric constant of air in air gaps (e.g., about 4 times of the dielectric constant of silicon oxide) can improve the insulation effect between vertical transistors 126 (and rows of DRAM cells 124) compared with some dielectrics (e.g., silicon oxide). Similarly, in some implementations, air gaps are formed laterally between word lines/gate electrodes 134 in the bit line direction as well (not shown), depending on the pitches of word lines/gate electrodes 134 in the bit line direction. In some implementations, instead of having the air gaps in the trench isolating region 160, a conductive material (e.g., metal such as W) is filled in the trench isolating region 160 and surrounded by the dielectric materials. As described with further details below, the conductive material in the trench isolating region 160 can be coupled out from the back side of the second semiconductor structure 104.

As shown in FIG. 1A, in some implementations, a capacitor 128 includes a first electrode 144 above and coupled to the first terminal 138 of vertical transistor 126, e.g., the upper end of the transistor body 130, via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. In some implementations, the first electrode 144 includes a filler structure 144a and a conductive layer 144b surrounding the filler structure 144a or covering at least one surface of the filler structure 144a. In some implementations, the filler structure 144a can include a filler material such as a dielectric material or polysilicon. The conductive layer 144b can include any suitable conductive material such as titanium nitride (TiN). In some implementations, the filler structure 144a extends along the Z direction and can have a pillar shape. In some implementations, the bottom portion (e.g., the second end 158 as shown in FIG. 1B) of the first electrode 144 is coupled to a first terminal 138 of a corresponding vertical transistor 126 via an ohmic contact (e.g., the capacitor contact 142 made of a metal silicide material). A capacitor body 145 including a dielectric material (e.g., a high-k material) can be deposited on at least part of surfaces of the first electrode 144 followed by the deposition of a second electrode 143. In other words, the capacitor body 145 is between the first electrode 144 and the second electrode 143, where the capacitor body 145 at least partially covers the first electrode 144 and the second electrode 143 at least partially covers the capacitor body 145. In some implementations, the capacitor body 145 can be referred to as a dielectric layer 145. The second electrode 143 can include one or more metallic layers that are stacked together. In some examples, e.g., as illustrated in FIG. 1A, the second electrode 143 is formed by depositing a first metallic layer 143a (e.g., TiN) on surface of the capacitor body 145 and a second metallic layer 143b (e.g., SiGe) on the first metallic layer 143a. One or more supporting structures 150 can be extending along a horizontal direction (e.g., in the X-Y plane). In some implementations, the supporting structures 150 can be distributed between the first electrodes 144 and the second electrodes 143, and/or between first electrodes 144 of two adjacent capacitors 128, e.g., as illustrated in FIG. 1A.

In some implementations, each first electrode 144 is coupled to the first terminal 138 of a respective vertical transistor 126 in the same DRAM cell via a capacitor contact 142 while all second electrodes are coupled to a common plate 146 coupled to the ground, e.g., a common ground. In some implementations, the capacitor 128 can have a first end in the negative Z direction and a second end opposite to the first end in the positive Z direction (not shown). In some implementations, the first end of the capacitor 128 is coupled to the first terminal 138 of the vertical transistor 126 via an ohmic contact (e.g., the capacitor contact 142 made of a metal silicide material). As shown in FIG. 1A, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the Z direction from the dielectric layer of the bonding layer 120 to couple to the second end of the capacitor 128 via the common plate 146, as shown in FIG. 1A. In some implementations, the ILD layer in which the capacitors 128 are formed has the same dielectric material as the ILD layers into which the transistor body 130 extends, such as silicon oxide.

It is understood that the structure and configuration of a capacitor 128 are not limited to the example in FIG. 1A and may include any suitable structure and configuration, such as a pillar capacitor, a cup capacitor, a planar capacitor, a stack capacitor, a multi-fins capacitor, a cylinder capacitor, a trench capacitor, or a substrate-plate capacitor. In some implementations, the capacitor body 145 includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 128 may be a ferroelectric capacitor used in a FRAM cell, and the capacitor body 145 may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1A, vertical transistor 126 extends vertically through and contacts the word lines 134, the second terminal 139 of vertical transistor 126 at the lower end thereof is in contact with the bit line 123, and the first terminal 138 of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 1A, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106. As a result, the interconnect layer 122 including bit lines 123 can be arranged close to the bonding interface 106 to reduce the interconnect routing distance and complexity.

As shown in FIG. 1A, the second semiconductor structure 104 can further include a pad-out interconnect layer 156 above the capacitors 128 and the DRAM cells 124. The pad-out interconnect layer 156 can include interconnects, e.g., contact pads 154, in one or more ILD layers. The pad-out interconnect layer 156 and the interconnect layer 122 can be formed on opposite sides of the DRAM cells 124. The capacitors 128 can be disposed vertically between the vertical transistors 126 and the pad-out interconnect layer 156. In some implementations, the interconnects in pad-out interconnect layer 156 can transfer electrical signals between the 3D semiconductor device 100 and outside circuits, e.g., for pad-out purposes.

In some implementations, the second semiconductor structure 104 further includes one or more contacts 152 extending through part of the pad-out interconnect layer 156 to couple the pad-out interconnect layer 156 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 156. Contact pads 154 and contacts 152 can include conductive materials including, but not limited to, W, Co, Cu, Al, silicides, or any combination thereof. In one example, the contact pad 154 may include Al, and the contact 152 may include W.

Although not shown, it is understood that the pad-out of 3D memory devices is not limited to from the second semiconductor structure 104 having DRAM cells 124 as shown in FIG. 1A and may be from the first semiconductor structure 102 having peripheral circuit 112. Although not shown, it is also understood that the air gaps between word lines 134 and/or between transistor bodies 130 may be partially or fully filled with dielectrics. Although not shown, it is further understood that more than one array of DRAM cells 124 may be stacked over one another to vertically scale up the number of DRAM cells 124.

Although not shown in FIG. 1A, it is understood that capacitors 128 can have an irregular shape (e.g., a trapezoid shape) in cross-section views, where one capacitor end, that is closer to first terminals 138 of vertical transistors 126 (e.g., source terminals) is wider than the other end of the capacitor. Likewise, vertical transistor bodies 130 can also have an irregular shape (e.g., a trapezoid shape) in cross-section views, where one end in contact with first terminals 138 of vertical transistors 126 (e.g., source terminals) is wider than the other end in contact with second terminals 139 of vertical transistors 126 (e.g., drain terminals). As such, when capacitors 128 and transistors 126 are vertically stacked together, this configuration (e.g., “back-to-back trapezoid”) can enhance alignment precision between vertical transistor arrays and capacitor arrays, which enables to form memory devices with narrower pitches.

Although not shown in FIG. 1A, it is understood that in some implementations, another side of the semiconductor structure 104 can be bonded to the semiconductor structure 102. For example, the capacitors 128, the vertical transistors 126, and the semiconductor structure 102 can be disposed along the vertical direction, and the capacitors 128 can be between the vertical transistors 126 and the semiconductor structure 102.

FIG. 1B illustrates an enlarged side view of the capacitors 128 and the supporting structures 150 of the 3D semiconductor device 100. The first electrode 144 of the capacitor 128 can have a first end 157 and a second end 158 on opposite sides along the Z direction. For example, the second end 158 of the first electrode 144 can be in contact with the capacitor contact 142 as shown in FIG. 1A. The first electrode 144 of the capacitor 128 can be in contact with a first supporting structure 150a, a second supporting structure 150b, and a third supporting structure 150c along a horizontal direction in the X-Y plane (e.g., a direction perpendicular to the vertical direction). In other words, the first electrode 144 is in contact with the first supporting structure 150a, the second supporting structure 150b, and the third supporting structure 150c. The first electrode 144 and the first supporting structure 150a are disposed along the horizontal direction, the first electrode 144 and the second supporting structure 150b are disposed along the horizontal direction, and the first electrode 144 and the third supporting structure 150c are disposed along the horizontal direction. In some implementations, the first supporting structure 150a and the second supporting structure 150b extend along the horizontal direction by different lengths. That is, along the horizontal direction, a size (e.g., size 159 as shown in FIG. 1B) of the first supporting structure 150a and a size (e.g., size 161 as shown in FIG. 1B) of the second supporting structure 150b are different. In some implementations, the second end 158 of the first electrode 144 is in contact with the third supporting structure 150c along the horizontal direction. That is, the second end 158 of the first electrode 144 and the third supporting structure 150c are disposed along the horizontal direction. As shown in FIG. 1B, the horizontal direction can be the Y direction.

In some implementations, a supporting structure (e.g., the first supporting structure 150a, the second supporting structure 150b, or the third supporting structure 150c) has a first end and a second end positioned along the horizontal direction. In some instances, as shown in FIG. 1B (e.g., the first supporting structure 150a), the first end of the supporting structure is in contact with the conductive layer 144b of the first electrode 144 of the capacitor 128 (referred to as capacitor 128a). The first end of the supporting structure and the conductive layer 144b of the first electrode 144 of the capacitor 128a are disposed along the horizontal direction. The second end of the supporting structure is in contact with the dielectric layer 145 of the capacitor 128a. The second end of the supporting structure and the dielectric layer 145 of the capacitor 128a are disposed along the horizontal direction. In other words, the supporting structure is sandwiched between the first electrode 144 and the dielectric layer 145 of the same capacitor (e.g., capacitor 128a of FIG. 1B) along the horizontal direction. In some other instances, as shown in FIG. 1B (e.g., the second supporting structure 150b or the third supporting structure 150c), the first end of the supporting structure is in contact with the conductive layer 144b of the first electrode 144 of the capacitor 128a. The first end of the supporting structure and the conductive layer 144b of the first electrode 144 of the capacitor 128a are disposed along the horizontal direction. The second end of the supporting structure is in contact with a first electrode of a capacitor 128b that is adjacent to the capacitor 128a. The second end of the supporting structure and the first electrode of the capacitor 128b are disposed along the horizontal direction. In other words, the supporting structure can be sandwiched between the first electrodes of two adjacent capacitors (e.g., the capacitors 128a and 128b of FIG. 1B).

In some implementations, the first end 157 of the first electrode 144 of the capacitor 128, the second end 158 of the first electrode 144 of the capacitor 128, the first supporting structure 150a, and the second supporting structure 150b are differently positioned along the vertical direction (e.g., the Z direction). In other words, the first supporting structure 150a and the second supporting structure 150b are between the first end 157 of the first electrode 144 and the second end 158 of the first electrode 144 along the Z direction. In some implementations, the first supporting structure 150a and the second supporting structure 150b each can form a protrusion sticking out from a surface of the first electrode 144 (e.g., along the Y direction). The first supporting structure 150a is closer to the first end 157 of the first electrode 144 than the second supporting structure 150b along the Z direction. The second supporting structure 150b is closer to the second end 158 of the first electrode 144 than the first supporting structure 150a along the Z direction. In some implementations, the first end 157 of the first electrode 144 of two or more capacitors 128 may not align along the Y direction. In some implementations, a distance between the first end 157 and the first supporting structure 150 along the Z direction can be in a range between 100 Nanometers (nm) and 500 nm. For example, the distance between the first end 157 and the first supporting structure 150 along the Z direction can be around 200 nm. In some implementations, the supporting structure (e.g., the first supporting structure 150a, the second supporting structure 150b, or the third supporting structure 150c) includes any suitable dielectric materials including, but not limited to, silicon boron nitride (SiBN), silicon carbon nitride (SiCN), or any combination thereof.

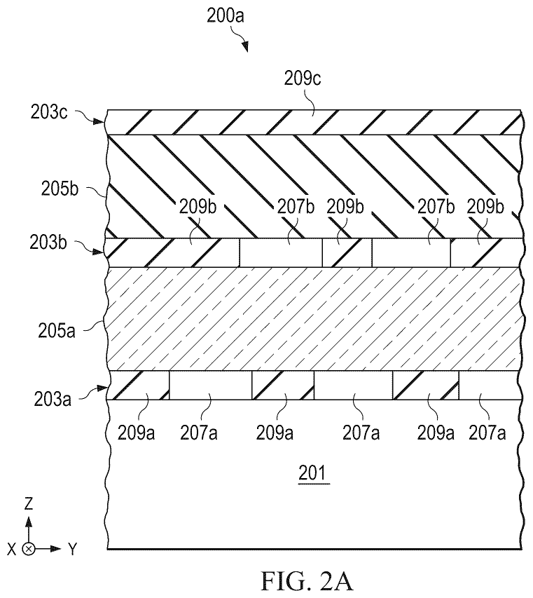

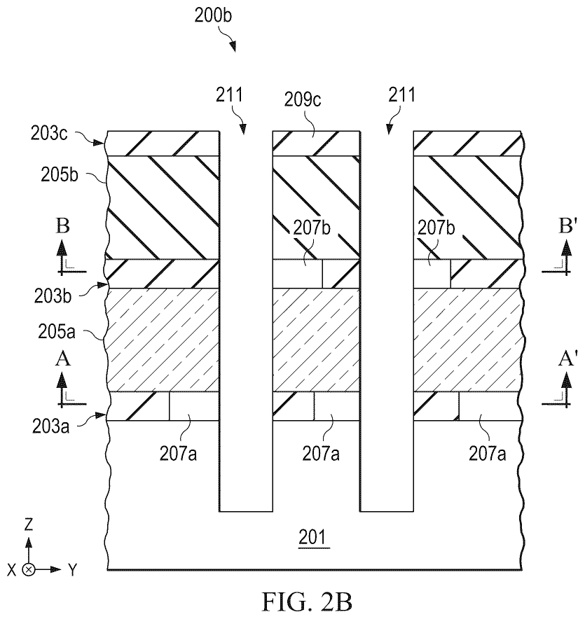

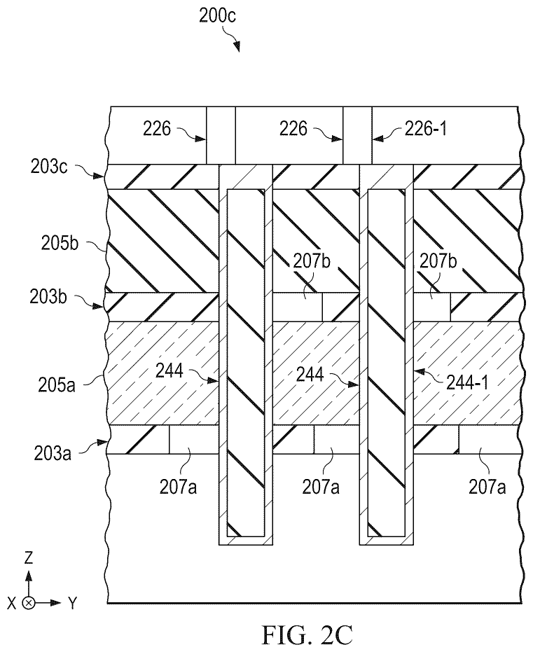

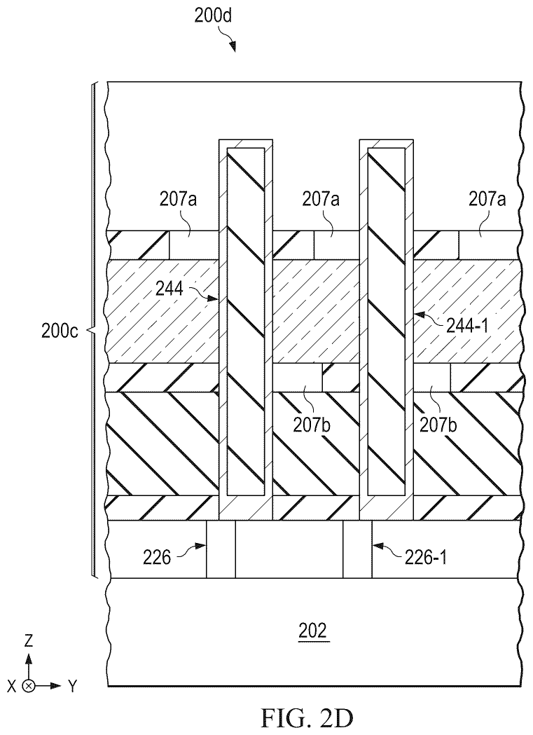

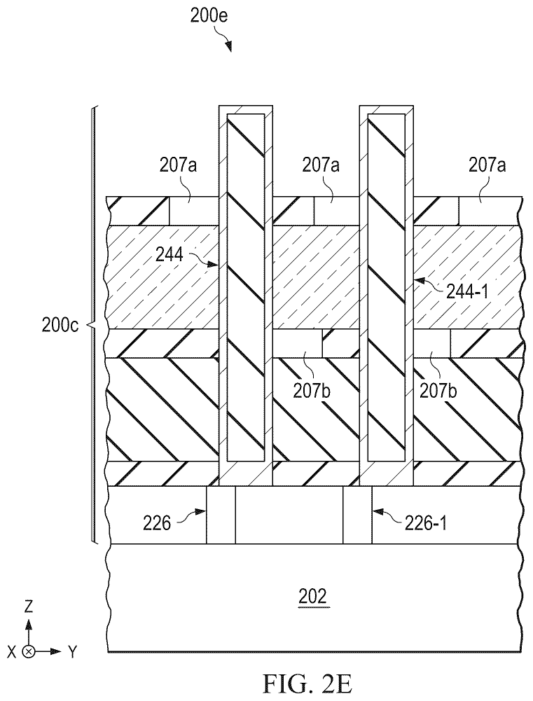

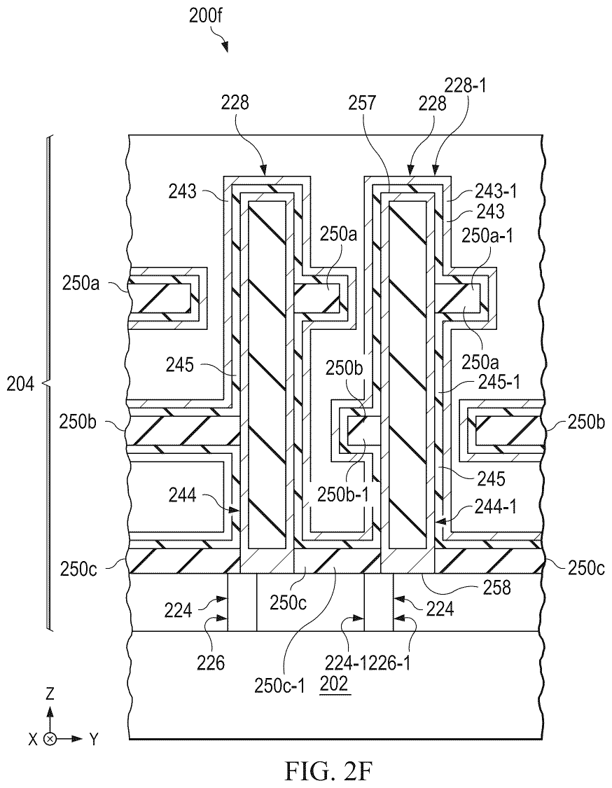

FIGS. 2A-2F illustrate an example process of fabricating a semiconductor device, such as the 3D semiconductor device 100 as illustrated in FIGS. 1A-1B. FIGS. 2A-2F show example semiconductor structures at various stages of the fabrication process.

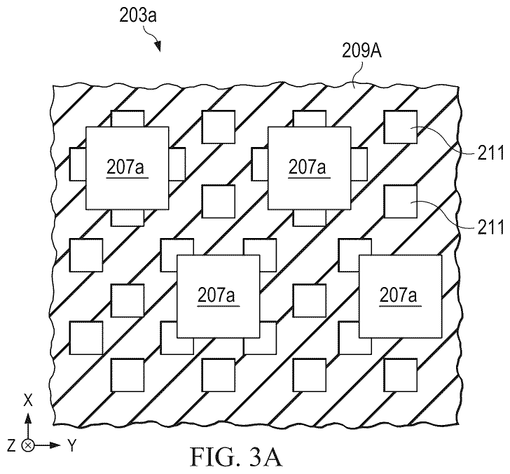

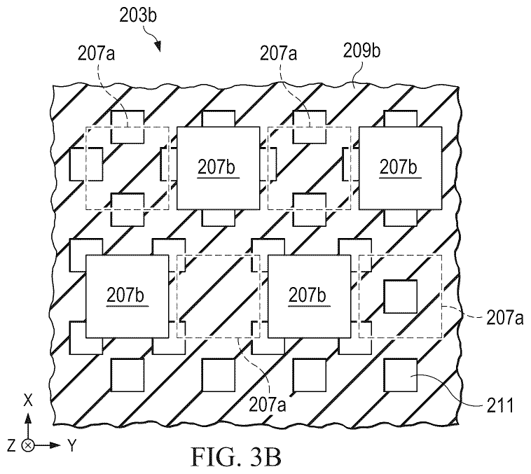

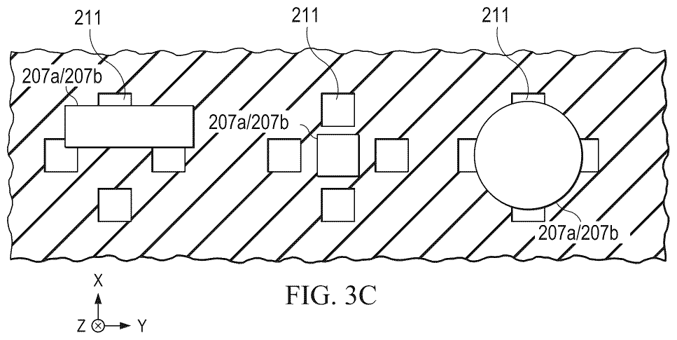

As shown in FIG. 2A, a semiconductor structure 200a is formed. The semiconductor structure 200a includes a substrate 201. The semiconductor structure 200a further includes a first supporting layer 203a, a first sacrificial layer 205a, a second supporting layer 203b, a second sacrificial layer 205b, and a third supporting layer 203c stacked on top of the substrate 201 along the Z direction. Although FIG. 2A illustrates three supporting layers (e.g., 203a, 203b, and 203c) and two sacrificial layers (e.g., 205a and 205b), it is understood that in practice the semiconductor structure 200a can have any suitable number (e.g., more than three) of supporting layers and any suitable number (e.g., more than two) of sacrificial layers. The first supporting layer 203a, the first sacrificial layer 205a, the second supporting layer 203b, the second sacrificial layer 205b, and the third supporting layer 203c can be deposited on top of the substrate 201 sequentially along the Z direction. The first sacrificial layer 205a is between the first supporting layer 203a and the second supporting layer 203b along the Z direction. The second sacrificial layer 205b is between the second supporting layer 203b and the third supporting layer 203c along the Z direction. The first supporting layer can include sacrificial pads 207a and a dielectric material 209a (e.g., SiBN or SiCN) isolating the sacrificial pads 207a along a horizontal direction (e.g., the Y direction). The second supporting layer 203b can include sacrificial pads 207b and a dielectric material 209b (e.g., SiBN or SiCN) isolating the sacrificial pads 207b along the Y direction. In some implementations, the sacrificial pads 207a and the sacrificial pads 207b have different layouts (e.g., as shown in FIGS. 3A-3C). The third supporting layer 203c can include a dielectric material 209c (e.g., SiBN or SiCN). In some implementations, the third supporting layer 203c may not include a sacrificial pad. In some implementations, the first sacrificial layer 205a can include a first sacrificial material, which can be silicon oxide such as Borophosphosilicate glass (BPSG), and the second sacrificial layer 205b can include a second sacrificial material, which can be silicon oxide such as Tetraethylorthosilicate (TEOS). The sacrificial materials in the first sacrificial layer 205a and the second sacrificial layer 205b can be etched off at a faster rate than the dielectric materials 209a, 209b, and 209c in the supporting layers 203a, 203b, and 203c. In some implementations, the sacrificial pads 207a and 207b also include materials that can be etched off at a faster rate than the dielectric materials 209a, 209b, and 209c. For example, the etching rate of the materials in the sacrificial pads 207a and 207b can be similar to, or same as, the etching rate of the sacrificial materials in the first sacrificial layer 205a and the second sacrificial layer 205b. In some implementations, the materials of the sacrificial pads 207a and 207b can include dielectric materials such as silicon oxide and silicon nitride and can be deposited using, for example, Atomic Layer Deposition (ALD) methods.

FIB. 2B illustrates a semiconductor structure 200b, which includes an array of capacitor holes 211 extending through the third supporting layer 203c, the second sacrificial layer 205b, the second supporting layer 203b, the first sacrificial layer 205a, and the first supporting layer 203a and into the substrate 201 along the Z direction. The capacitor holes 211 can be formed, for example, by an etching process.

FIGS. 3A-3C illustrate example layouts of the capacitor holes 211, the sacrificial pads 207a in the first supporting layer 203a, and the sacrificial pads 207b in the second supporting layer 203b. FIG. 3A shows a cross-sectional view of the first supporting layer 203a along a cut line AA′ of FIG. 2B. As shown in FIG. 3A, the capacitor holes 211 and the sacrificial pads 207a are isolated by the dielectric material 209a in the X-Y plane. FIG. 3B shows a cross-sectional view of the second supporting layer 203b along a cut line BB′ of FIG. 2B. As shown in FIG. 3B, the capacitor holes 211 and the sacrificial pads 207b are isolated by the dielectric material 209b in the X-Y plane. In some implementations, the sacrificial pads 207a and the sacrificial pads 207b have different layouts. For example, as shown in FIG. 3B, the layout of the sacrificial pads 207a in the first supporting layer 203a is not aligned with the layout of the sacrificial pads 207b in the second supporting layer 203b along the vertical direction (e.g., the Z direction). While FIGS. 3A-3B show that in the X-Y plane, a cross section of each of the sacrificial pads 207a and 207b can be in a square shape and can have a larger size than a cross section of each capacitor hole 211, it is understood that the examples in these figures are not intended to be construed in a limiting sense. In some implementations, the sacrificial pads 207a and 207b can have any suitable shapes and sizes. For example, as shown in FIG. 3C, the sacrificial pad 207a or 207b can have a rectangular or circular cross section (e.g., in the X-Y plane), and the size of the cross section of the sacrificial pad 207a or 207b can be similar to, or same as the size of the cross section of the capacitor hole 211.

FIB. 2C illustrates a semiconductor structure 200c including a first array of electrodes 244. Each of the first array of electrodes 244 is in a respective capacitor hole of the array of capacitor holes 211. The first array of electrodes 244 can be formed by depositing a conductive material (e.g., TiN) on inner surfaces of the array of capacitor holes 211 and filling a filler material into the array of capacitor holes 211. The filler material can include a dielectric material or polysilicon. The first array of electrodes 244 includes a first electrode 244-1.

The semiconductor structure 200c further includes an array of vertical transistors 226, which can be formed by any suitable fabrication processes. Each vertical transistor of the array of vertical transistors 226 can be stacked over a respective electrode of the first array of electrodes 244. For example, the array of vertical transistors 226 can include a vertical transistor 226-1 stacked over and coupled to the first electrode 244-1. Each vertical transistor 226 can be similar to, or same as the vertical transistor 126 of FIG. 1A. For example (not shown in FIG. 2C), the vertical transistor 226 can include a transistor body and a gate structure. The transistor body can have a first terminal and a second terminal on opposite ends of the transistor body along the Z direction. The gate structure can be adjacent to the transistor body along the Y direction. The first terminal can be in contact with the electrode 244. The first terminal and the electrode 244 can be disposed along the Z direction. The transistor body can include at least one of polysilicon, IGZO, or IGSO. The gate structure can include one of a single-side gate structure, a dual-side gate structure, a triple-side gate structure, or a GAA structure.

As shown in FIG. 2D, a semiconductor structure 200d can be formed by flipping the semiconductor structure 200c upside down and bonding the semiconductor structure 200c to a semiconductor structure 202. The semiconductor structure 202 can be an example of the semiconductor structure 102 of FIG. 1A. For example, the semiconductor structure 202 can include a control circuit (not shown in FIG. 2D) configured to control the semiconductor structure 200c.

As shown in FIG. 2E, a semiconductor structure 200e is formed by removing the substrate 201 of the semiconductor structure 200c.

FIG. 2F illustrates a semiconductor structure 200f including a semiconductor structure 204 and the semiconductor structure 202. The semiconductor structure 204 can be formed from the semiconductor structure 200c in FIG. 2E, for example, by the following process. First, the sacrificial pads 207a in the first supporting layer 203a, the first sacrificial layer 205a, the sacrificial pads 207b in the second supporting layer 203b, and the second sacrificial layer 205b can be removed (e.g., by a same etching process). The etching process can be a wet etching and can also be referred to as a dipping out process. The sacrificial pads (e.g., the sacrificial pads 207a and 207b) can be etched off by an etchant used in the etching process, thereby creating space in the supporting layers and allowing the etchant to flow from the top of the semiconductor structure 200c to the first sacrificial layer 205a and the second sacrificial layer 205b through the created space. Thus, the first sacrificial layer 205a and the second sacrificial layer 205b can be removed by the same etching process. A remaining part (e.g., the dielectric material 209a) of the first supporting layer 203a can form supporting structures 250a. The supporting structures 250a include a supporting structure 250a-1 that is in contact with the first electrode 244-1. A remaining part of the second supporting layer 203b can form supporting structures 250b. The supporting structures 250b include a supporting structure 250b-1 that is in contact with the first electrode 244-1. The third supporting layer 203c (which may not be etched off by the above-mentioned etching process) can from supporting structures 250c. The supporting structures 250c include a supporting structure 250c-1 that is in contact with the first electrode 244-1. In addition, an array of capacitor bodies 245 can be formed by depositing a dielectric layer surrounding the first array of electrodes 244, the remaining part of the first supporting layer 203a, and the remaining part of the second supporting layer 203b. The array of capacitor bodies 245 includes a capacitor body 245-1 that is in contact with the first electrode 244-1 and the supporting structures 250a-1, 250b-1, and 250c-1. Furthermore, a second array of electrodes 243 can be formed by depositing at least one conductive layer surrounding the dielectric layer (e.g., the array of capacitor bodies 245). The second array of electrodes 243 includes a second electrode 243-1 that is in contact with the capacitor body 245-1. As a result, an array of capacitors 228 including a capacitor 228-1 can be formed. Each capacitor 228 includes a capacitor body or a dielectric layer of the array of capacitor bodies 245 between a corresponding electrode of the first array of electrodes 244 and a corresponding electrode of the second array of electrodes 243. For example, the capacitor 228-1 includes the first electrode 244-1, the capacitor body or dielectric layer 245-1, and the second electrode 243-1. An array of memory cells 224 are formed. Each memory cell 224 (e.g., memory cell 224-1 as shown in FIG. 2F) includes a vertical transistor (e.g., vertical transistor 226-1) of the vertical transistors 226 and a corresponding capacitor (e.g., capacitor 228-1) of the capacitors 228 stacked over the vertical transistor. The semiconductor structure 200f can be similar to, or same as, the 3D semiconductor device 100 of FIGS. 1A-1B. The semiconductor structure 204 can be an example of the semiconductor structure 104 of FIG. 1A. The capacitor 228 can be similar to, or same as, the capacitor 128 of the 3D semiconductor device 100. The vertical transistor 226 can be similar to, or same as, the vertical transistor 126 of the 3D semiconductor device 100. The semiconductor structure 204 can further include other components, such as bit lines, one or more interconnect layers, and a bonding structure between the semiconductor structures 202 and 204, which can be formed by any suitable fabrication process.

In some implementations, as shown in FIG. 2F, the first electrode 244-1 of the capacitor 228-1 is in contact with the supporting structure 250a-1 and the supporting structure 250b-1. The first electrode 244-1 of the capacitor 228-1 and the supporting structure 250a-1 are disposed along a horizontal direction (e.g., the Y direction). The first electrode 244-1 of the capacitor 228-1 and the supporting structure 250b-1 are disposed along the horizontal direction. The supporting structure 250a-1 and the supporting structure 250b-1 extend along the horizontal direction by different lengths. The supporting structure 250a-1 and the supporting structure 250b-1 are between a first end 257 of the first electrode 244-1 of the capacitor 228-1 and a second end 258 of the first electrode 244-1 of the capacitor 228-1 along the vertical direction. The supporting structure 250a-1 is closer to the first end 257 of the first electrode 244-1 of the capacitor 228-1 than the supporting structure 250b-1 along the vertical direction. The supporting structure 250b-1 is closer to the second end 258 of the first electrode 244-1 of the capacitor 228-1 than the supporting structure 250a-1 along the vertical direction.

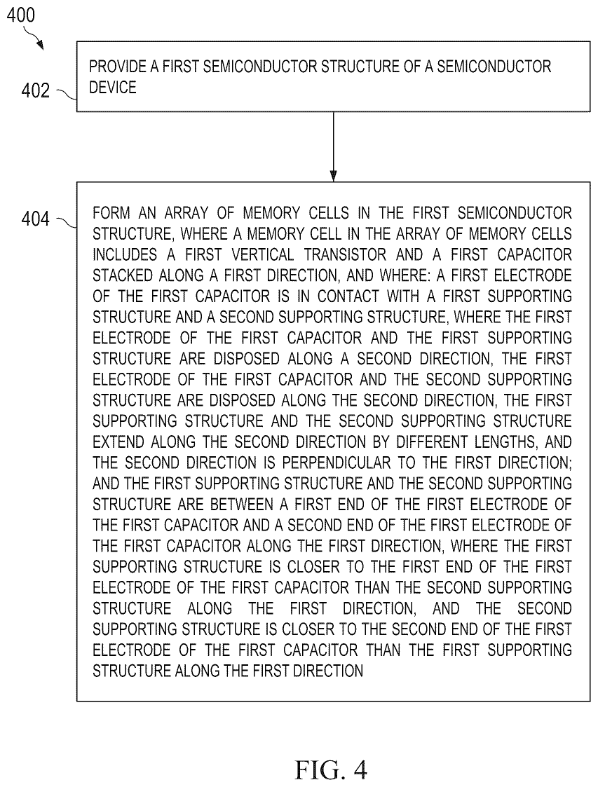

FIG. 4 illustrates a flow chart of an example process 400. The process 400 can be performed to form a semiconductor device (e.g., the 3D semiconductor device 100 illustrated by FIGS. 1A-1B). The process 400 can be described in view of FIGS. 2A-2F. The process 400 can include one or more steps of the fabrication process of forming the semiconductor structures in FIGS. 2A-2F. It is understood that the operations shown in process 400 are not exhaustive and that other operations can be performed as well before, after, or between any of the illustrated operations. Further, some of the operations may be performed simultaneously, or in a different order than shown in FIG. 4.

At operation 402, a first semiconductor structure (e.g., the semiconductor structures 200a-200e and 204 of FIGS. 2A-2F) of the semiconductor device is provided.

At operation 404, an array of memory cells (e.g., memory cells 224 of FIG. 2F) in the first semiconductor structure (e.g., semiconductor structure 204 of FIG. 2F) is formed. A memory cell (e.g., memory cell 224-1 of FIG. 2F) in the array of memory cells includes a first vertical transistor (e.g., vertical transistor 226-1 of FIG. 2F) and a first capacitor (e.g., capacitor 228-1 of FIG. 2F) stacked along a first direction (e.g., a vertical direction such as the Z direction). A first electrode (e.g., first electrode 244-1 of FIG. 2F) of the first capacitor is in contact with a first supporting structure (e.g., supporting structure 250a-1 of FIG. 2F) and a second supporting structure (e.g., supporting structure 250b-1 of FIG. 2F). The first electrode of the first capacitor and the first supporting structure are disposed along a second direction (e.g., a horizontal direction such as the Y direction). The first electrode of the first capacitor and the second supporting structure are disposed along the second direction. The first supporting structure and the second supporting structure extend along the second direction by different lengths. The second direction is perpendicular to the first direction. The first supporting structure and the second supporting structure are between a first end (e.g., end 257 of FIG. 2F) of the first electrode of the first capacitor and a second end (e.g., end 258 of FIG. 2F) of the first electrode of the first capacitor along the first direction. The first supporting structure is closer to the first end of the first electrode of the first capacitor than the second supporting structure along the first direction. The second supporting structure is closer to the second end of the first electrode of the first capacitor than the first supporting structure along the first direction.

In some implementations, forming the array of memory cells includes forming an array of capacitors (e.g., capacitors 228 of FIG. 2F) including the first capacitor (e.g., capacitor 228-1 of FIG. 2F) and forming an array of vertical transistors (e.g., vertical transistors 226 of FIG. 2F) including the first vertical transistor (e.g., vertical transistor 226-1 of FIG. 2F). Forming the array of capacitors includes forming a first supporting layer (e.g., the supporting layer 203a of FIG. 2A), a first sacrificial layer (e.g., the sacrificial layer 205a of FIG. 2A), a second supporting layer (e.g., the supporting layer 203b of FIG. 2A), a second sacrificial layer (e.g., the sacrificial layer 205b of FIG. 2A), and a third supporting layer (e.g., the supporting layer 203c of FIG. 2A) stacked on top of a substrate (e.g., the substrate 201 of FIG. 2A) of the first semiconductor structure along the first direction. The first sacrificial layer is between the first supporting layer and the second supporting layer along the first direction. The second sacrificial layer is between the second supporting layer and the third supporting layer along the first direction. The first supporting layer includes first sacrificial pads (e.g., the sacrificial pads 207a of FIG. 2A) and a first dielectric material (e.g., the dielectric material 209a of FIG. 2A) isolating the first sacrificial pads along the second direction. The second supporting layer includes second sacrificial pads (e.g., the sacrificial pads 207b of FIG. 2A) and a second dielectric material (e.g., the dielectric material 209b of FIG. 2A) isolating the second sacrificial pads along the second direction. The first sacrificial pads and the second sacrificial pads have different layouts (e.g., as shown in FIGS. 3A-3C). The third supporting layer includes a third dielectric material (e.g., the dielectric material 209c of FIG. 2A).

In some implementations, forming the array of capacitors further includes: forming an array of capacitor holes (e.g., the capacitor holes 211 of FIG. 2B) extending through the third supporting layer, the second sacrificial layer, the second supporting layer, the first sacrificial layer, and the first supporting layer and into the substrate along the first direction; and forming a first array of electrodes (e.g., the electrodes 244 of FIG. 2C) by depositing a conductive material on inner surfaces of the array of capacitor holes and filling a filler material into the array of capacitor holes. The first array of electrodes includes the first electrode (e.g., the first electrode 244-1 of FIG. 2C).

In some implementations, forming the array of vertical transistors includes forming the array of vertical transistors on top of the third supporting layer (e.g., as described with reference to FIG. 2C). The first vertical transistor (e.g., the vertical transistor 226-1 of FIG. 2C and the vertical transistor 126 of FIG. 1A) includes a transistor body and a gate structure. The transistor body has a first terminal and a second terminal on opposite ends of the transistor body along the first direction. The gate structure is adjacent to the transistor body along the second direction. The first terminal is in contact with the first electrode. The first terminal and the first electrode are disposed along the first direction. The transistor body includes at least one of polysilicon, indium gallium zinc oxide (IGZO), or indium gallium silicon oxide (IGSO). The gate structure includes one of a single-side gate structure, a dual-side gate structure, a triple-side gate structure, or a gate-all-around (GAA) structure.

In some implementations, the process 400 further includes: flipping the first semiconductor structure upside down (e.g., as described with reference to FIG. 2D); bonding (e.g., as described with reference to FIG. 2D) the first semiconductor structure to a second semiconductor structure (e.g., the semiconductor structure 202 of FIG. 2D) including a control circuit; and removing the substrate (e.g., as described with reference to FIG. 2E).

In some implementations, forming the array of capacitors further includes removing the first sacrificial pads in the first supporting layer, the first sacrificial layer, the second sacrificial pads in the second supporting layer, and the second sacrificial layer by a same etching process (e.g., as described with reference to FIG. 2F). A remaining part of the first supporting layer includes the first supporting structure (e.g., the supporting structure 250a-1 of FIG. 2F). A remaining part of the second supporting layer includes the second supporting structure (e.g., the supporting structure 250b-1 of FIG. 2F).

In some implementations, forming the array of capacitors further includes forming an array of capacitor bodies (e.g., the capacitor bodies 245 of FIG. 2F) by depositing a dielectric layer surrounding the first array of electrodes and the remaining part of the first supporting layer and the remaining part of the second supporting layer. The array of capacitor bodies includes a capacitor body (e.g., the capacitor body 245-1 of FIG. 2F) of the first capacitor (e.g., the capacitor 228-1 of FIG. 2F) formed by a portion of the dielectric layer that is in contact with the first electrode, the first supporting structure, and the second supporting structure. Forming the array of capacitors further includes forming a second array of electrodes (e.g., the second array of electrodes 243 of FIG. 2F) by depositing at least one conductive layer surrounding the dielectric layer. The second array of electrodes includes a second electrode (e.g., the second electrode 243-1 of FIG. 2F) of the first capacitor formed by a portion of the at least one conductive layer that is in contact with the capacitor body of the first capacitor.

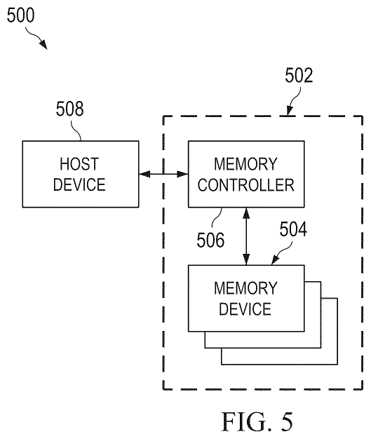

FIG. 5 illustrates a block diagram of an example system 500. The system 500 can have one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 5, the system 500 can include a host device 508 and a memory system 502 having one or more memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more memory devices 504.

A memory device 504 can be any memory device disclosed in the present disclosure, such as a memory device (e.g., a 3D DRAM device) as shown in FIGS. 1A-1B. Memory controller 506 (a.k.a., a controller circuit) is coupled to memory device 504 and host device 508. Consistent with implementations of the present disclosure, memory device 504 can include a plurality of conductive interconnections through a cover layer that are in contact with conductive pads in a conductive pad layer, and memory controller 506 can be coupled to memory device 504 through at least one of the plurality of conductive interconnections. Memory controller 506 is configured to control memory device 504. For example, memory controller 506 may be configured to operate a plurality of channel structures via word lines. Memory controller 506 can manage data stored in memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of memory device 504, such as read, erase, and program (or write) operations. Memory controller 506 can also be configured to manage various functions with respect to the data stored or to be stored in memory device 504 including, but not limited to bad-block management, garbage collection, logical-to-physical address conversion, wear leveling, etc. In some implementations, memory controller 506 is further configured to process error correction codes (ECCs) with respect to the data read from or written to memory device 504. Any other suitable functions may be performed by memory controller 506 as well, for example, formatting memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
an array of memory cells, wherein a memory cell in the array of memory cells comprises a first vertical transistor and a first capacitor stacked along a first direction, and wherein:
the first capacitor comprises a first electrode comprising a filler structure and a conductive layer surrounding the filler structure;
the first electrode of the first capacitor is in contact with a first supporting structure and a second supporting structure, wherein the first electrode of the first capacitor and the first supporting structure are disposed along a second direction, the first electrode of the first capacitor and the second supporting structure are disposed along the second direction, the first supporting structure and the second supporting structure extend along the second direction by different lengths, and the second direction is perpendicular to the first direction; and
the first supporting structure and the second supporting structure are between a first end of the first electrode of the first capacitor and a second end of the first electrode of the first capacitor along the first direction, wherein the first supporting structure is closer to the first end of the first electrode of the first capacitor than the second supporting structure along the first direction, and the second supporting structure is closer to the second end of the first electrode of the first capacitor than the first supporting structure along the first direction.

2. The semiconductor device of claim 1, wherein the second end of the first electrode of the first capacitor is in contact with a third supporting structure, and the second end of the first electrode of the first capacitor and the third supporting structure are disposed along the second direction.

3. The semiconductor device of claim 1, wherein the first capacitor further comprises a dielectric layer and a second electrode, the dielectric layer is in contact with the conductive layer of the first electrode of the first capacitor, and the second electrode of the first capacitor is in contact with the dielectric layer of the first capacitor.

4. The semiconductor device of claim 3, wherein the first supporting structure has a first end and a second end positioned along the second direction, the first end is in contact with the conductive layer of the first electrode of the first capacitor, the first end and the conductive layer of the first electrode of the first capacitor are disposed along the second direction, the second end is in contact with the dielectric layer of the first capacitor, and the second end and the dielectric layer of the first capacitor are disposed along the second direction.

5. The semiconductor device of claim 1, wherein the array of memory cells comprises a second capacitor adjacent to the first capacitor, the first supporting structure has a first end and a second end positioned along the second direction, the first end is in contact with the conductive layer of the first electrode of the first capacitor, the first end and the conductive layer of the first electrode of the first capacitor are disposed along the second direction, the second end is in contact with a first electrode of the second capacitor, and the second end and the first electrode of the second capacitor are disposed along the second direction.

6. The semiconductor device of claim 1, wherein:
the semiconductor device comprises a first semiconductor structure and a second semiconductor structure connected to the first semiconductor structure;
the first semiconductor structure comprises the array of memory cells; and
the second semiconductor structure comprises a control circuit configured to control the array of memory cells.

7. The semiconductor device of claim 6, wherein:
the first semiconductor structure is bonded to the second semiconductor structure through a bonding structure;
the first capacitor is coupled to the control circuit through the bonding structure;
the first vertical transistor, the first capacitor, and the bonding structure are disposed along the first direction; and
the first vertical transistor is positioned between the first capacitor and the bonding structure.

8. The semiconductor device of claim 1, wherein the filler structure of the first electrode of the first capacitor comprises polysilicon, and the conductive layer of the first electrode of the first capacitor comprises titanium nitride (TiN).

9. The semiconductor device of claim 1, wherein the first vertical transistor comprises a transistor body and a gate structure, the transistor body extends along the first direction and comprises a first terminal and a second terminal opposite to the first terminal, the gate structure is adjacent to the transistor body, the gate structure and the transistor body are disposed along the second direction, the first terminal is in contact with the first electrode of the first capacitor, and the first terminal and the first electrode of the first capacitor are disposed along the first direction.

10. The semiconductor device of claim 9, wherein the transistor body comprises at least one of polysilicon, indium gallium zinc oxide (IGZO), or indium gallium silicon oxide (IGSO).

11. The semiconductor device of claim 9, wherein the gate structure comprises one of a single-side gate structure, a dual-side gate structure, a triple-side gate structure, or a gate-all-around (GAA) structure.

12. A method of forming a semiconductor device, the method comprising:
providing a first semiconductor structure of the semiconductor device; and
forming an array of memory cells in the first semiconductor structure, wherein a memory cell in the array of memory cells comprises a first vertical transistor and a first capacitor stacked along a first direction, and wherein:
a first electrode of the first capacitor is in contact with a first supporting structure and a second supporting structure, wherein the first electrode of the first capacitor and the first supporting structure are disposed along a second direction, the first electrode of the first capacitor and the second supporting structure are disposed along the second direction, the first supporting structure and the second supporting structure extend along the second direction by different lengths, and the second direction is perpendicular to the first direction; and
the first supporting structure and the second supporting structure are between a first end of the first electrode of the first capacitor and a second end of the first electrode of the first capacitor along the first direction, wherein the first supporting structure is closer to the first end of the first electrode of the first capacitor than the second supporting structure along the first direction, and the second supporting structure is closer to the second end of the first electrode of the first capacitor than the first supporting structure along the first direction.

13. The method of claim 12, wherein forming the array of memory cells comprises forming an array of capacitors comprising the first capacitor and forming an array of vertical transistors comprising the first vertical transistor, and wherein forming the array of capacitors comprises:
forming a first supporting layer, a first sacrificial layer, a second supporting layer, a second sacrificial layer, and a third supporting layer stacked on top of a substrate of the first semiconductor structure along the first direction, wherein:
the first sacrificial layer is between the first supporting layer and the second supporting layer along the first direction;
the second sacrificial layer is between the second supporting layer and the third supporting layer along the first direction;
the first supporting layer comprises first sacrificial pads and a first dielectric material isolating the first sacrificial pads along the second direction;
the second supporting layer comprises second sacrificial pads and a second dielectric material isolating the second sacrificial pads along the second direction, wherein the first sacrificial pads and the second sacrificial pads have different layouts; and
the third supporting layer comprises a third dielectric material.

14. The method of claim 13, wherein forming the array of capacitors further comprises:
forming an array of capacitor holes extending through the third supporting layer, the second sacrificial layer, the second supporting layer, the first sacrificial layer, and the first supporting layer and into the substrate along the first direction; and
forming a first array of electrodes by depositing a conductive material on inner surfaces of the array of capacitor holes and filling a filler material into the array of capacitor holes, wherein the first array of electrodes comprises the first electrode.

15. The method of claim 14, wherein forming the array of vertical transistors comprises:
forming the array of vertical transistors on top of the third supporting layer, wherein the first vertical transistor comprises a transistor body and a gate structure, the transistor body has a first terminal and a second terminal on opposite ends of the transistor body along the first direction, the gate structure is adjacent to the transistor body along the second direction, the first terminal is in contact with the first electrode, the first terminal and the first electrode are disposed along the first direction, the transistor body comprises at least one of polysilicon, indium gallium zinc oxide (IGZO), or indium gallium silicon oxide (IGSO), and the gate structure comprises one of a single-side gate structure, a dual-side gate structure, a triple-side gate structure, or a gate-all-around (GAA) structure.

16. The method of claim 15, wherein the method further comprises:
flipping the first semiconductor structure upside down;
bonding the first semiconductor structure to a second semiconductor structure comprising a control circuit; and
removing the substrate.

17. The method of claim 16, wherein forming the array of capacitors further comprises:
removing the first sacrificial pads in the first supporting layer, the first sacrificial layer, the second sacrificial pads in the second supporting layer, and the second sacrificial layer by a same etching process, wherein a remaining part of the first supporting layer comprises the first supporting structure, and a remaining part of the second supporting layer comprises the second supporting structure.

18. The method of claim 17, wherein forming the array of capacitors further comprises:
forming an array of capacitor bodies by depositing a dielectric layer surrounding the first array of electrodes and the remaining part of the first supporting layer and the remaining part of the second supporting layer, wherein the array of capacitor bodies comprises a capacitor body of the first capacitor formed by a portion of the dielectric layer that is in contact with the first electrode, the first supporting structure, and the second supporting structure; and
forming a second array of electrodes by depositing at least one conductive layer surrounding the dielectric layer, wherein the second array of electrodes comprises a second electrode of the first capacitor formed by a portion of the at least one conductive layer that is in contact with the capacitor body of the first capacitor.

19. A memory system, comprising a memory device and a memory controller coupled to the memory device and configured to control the memory device, wherein the memory device comprises:
an array of memory cells, a memory cell in the array of memory cells comprising a first vertical transistor and a first capacitor stacked along a first direction, wherein:
the first capacitor comprises a first electrode comprising a filler structure and a conductive layer surrounding the filler structure;
the first electrode of the first capacitor is in contact with a first supporting structure and a second supporting structure, wherein the first electrode of the first capacitor and the first supporting structure are disposed along a second direction, the first electrode of the first capacitor and the second supporting structure are disposed along the second direction, the first supporting structure and the second supporting structure extend along the second direction by different lengths, and the second direction is perpendicular to the first direction; and
the first supporting structure and the second supporting structure are between a first end of the first electrode of the first capacitor and a second end of the first electrode of the first capacitor along the first direction, wherein the first supporting structure is closer to the first end of the first electrode of the first capacitor than the second supporting structure along the first direction, and the second supporting structure is closer to the second end of the first electrode of the first capacitor than the first supporting structure along the first direction.

20. The memory system of claim 19, wherein the first capacitor further comprises a dielectric layer and a second electrode, the dielectric layer is in contact with the conductive layer of the first electrode of the first capacitor, and the second electrode of the first capacitor is in contact with the dielectric layer of the first capacitor.
